(19) United States
(12) Patent Application Publication
(10) Pub. No.: US 2018/0185856 A1
(43) Pub. Date: Jul. 5, 2018

(54) LIQUID PROCESSING APPARATUS AND LIQUID PROCESSING METHOD

(71) Applicant: TOKYO ELECTRON LIMITED, Minato-ku (JP)

(72) Inventors: Hirofumi TAKEGUCHI, Koshi City (JP); Terufumi WAKIYAMA, Koshi City (JP); Norihiro ITO, Koshi City (JP)

(73) Assignee: TOKYO ELECTRON LIMITED, Minato-ku (JP)

(21) Appl. No.: 15/857,693

(22) Filed: Dec. 29, 2017

(30) Foreign Application Priority Data
Jan. 4, 2017 (JP) 2017-000273

(51) Int. Cl. B05B 1/16; B05C 11/10; B05D 1/00; H01L 21/306; H01L 21/67

(52) U.S. Cl. CPC B05B 1/1609; B05C 11/1002; H01L 21/6708; H01L 21/30604; B05D 1/002

(57) ABSTRACT

A liquid processing apparatus includes a holding device, a rotation device, and a processing fluid supply device including a nozzle positioned to face a surface of a substrate, a first supply path connected to the nozzle, and a second supply path connected to the nozzle such that the supply device supplies processing liquid to the substrate. The nozzle has a common flow path extending in radial direction from center portion toward peripheral portion of the substrate, and discharge ports connected to the common path and positioned in the radial direction, the first path is connected to the common path and supplies first liquid to the common path, the second path is connected to the common path and supplies second liquid to the common path that is different from the first liquid in temperature and/or concentration, and the first and second paths are communicatively connected each other via the common path.

### CROSS-REFERENCE TO RELATED APPLICATIONS

The present application is based upon and claims the benefit of priority to Japanese Patent Application No. 2017-000273, filed Jan. 4, 2017, the entire contents of which are incorporated herein by reference.

### BACKGROUND OF THE INVENTION

### Field of the Invention

The present invention relates to a liquid processing apparatus and a liquid processing method for applying a liquid to a substrate.

### Description of Background Art

In a process for manufacturing a semiconductor device, a process of supplying a chemical liquid to a substrate such as a silicon wafer or a compound semiconductor wafer is performed. For example, Japanese Translation of PCT International Application Publication No. 2010-528470 describes a technology in which a nozzle is positioned at a center portion of a rotating substrate and thereafter an etching liquid such as HF (hydrogen fluoride) is supplied from the nozzle to the rotating substrate and thereby a silicon film forming on the substrate is removed by etching. The entire contents of this publication are incorporated herein by reference.

### SUMMARY OF THE INVENTION

According to one aspect of the present invention, a liquid processing apparatus Includes a holding device that holds a substrate, a rotation device that rotates the substrate held by the holding device, and a processing fluid supply device including a nozzle positioned to face a surface of the substrate, a first supply path connected to the nozzle, and a second supply path connected to the nozzle such that the processing fluid supply device supplies a processing liquid to the substrate. The nozzle of the processing fluid supply device has a common flow path extending in a radial direction from a center portion toward a peripheral portion of the substrate, and multiple discharge ports connected to the common flow path and positioned in the radial direction, the first supply path of the processing fluid supply device is connected to the common flow path on a periphery side of the substrate and supplies a first liquid to the common flow path, the second supply path of the processing fluid supply device is connected to the common flow path on a center side of the substrate and supplies a second liquid to the common flow path such that the second liquid is different from the first liquid in temperature and/or concentration, and the first supply path and the second supply path of the processing fluid supply device are communicatively connected to each other via the common flow path.

According to another aspect of the present invention, a liquid processing method includes holding a substrate with a holding device that holds the substrate, rotating the substrate with a rotation device that rotates the substrate held by the holding device, and supplying, to the substrate, a processing liquid from a processing fluid supply device including a nozzle positioned to face a surface of the substrate, a first supply path connected to the nozzle, and a second supply path connected to the nozzle such that the processing fluid supply device supplies the processing liquid to the substrate. The nozzle of the processing fluid supply device has a common flow path extending in a radial direction from a center portion toward a peripheral portion of the substrate, and multiple discharge ports connected to the common flow path and positioned in the radial direction, the first supply path of the processing fluid supply device is connected to the common flow path on a periphery side of the substrate and supplies a first liquid to the common flow path, the second supply path of the processing fluid supply device is connected to the common flow path on a center side of the substrate and supplies a second liquid to the common flow path such that the second liquid is different from the first liquid in temperature and/or concentration, the first supply path and the second supply path of the processing fluid supply device are communicatively connected to each other via the common flow path, and the first liquid including a first etching liquid is supplied from the first supply path to the common flow path and the second liquid including a second etching liquid is supplied from the second supply path to the common flow path such that temperature and/or concentration of the second etching liquid is lower than temperature and/or concentration of the first etching liquid.

According to yet another aspect of the present invention, a liquid processing method includes holding a substrate with a holding device that holds the substrate, rotating the substrate with a rotation device that rotates the substrate held by the holding device, and supplying, to the substrate, a processing liquid from a processing fluid supply device including a nozzle positioned to face a surface of the substrate, a first supply path connected to the nozzle, and a second supply path connected to the nozzle such that the processing fluid supply device supplies the processing liquid to the substrate. The nozzle of the processing fluid supply device has a common flow path extending in a radial direction from a center portion toward a peripheral portion of the substrate, and multiple discharge ports connected to the common flow path and positioned in the radial direction, the first supply path of the processing fluid supply device is connected to the common flow path on a periphery side of the substrate and supplies a first liquid to the common flow path, the second supply path of the processing fluid supply device is connected to the common flow path on a center side of the substrate and supplies a second liquid to the common flow path such that the second liquid is different from the first liquid in temperature and/or concentration, the first supply path and the second supply path of the processing fluid supply device are communicatively connected to each other via the common flow path, and the first liquid including a first temperature adjustment liquid is supplied from the first supply path to the common flow path and the second liquid including a second temperature adjustment liquid is supplied from the second supply path to the common flow path such that a temperature of the second temperature adjustment liquid is lower than a temperature of the first temperature adjustment liquid.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic diagram illustrating a structural example of a liquid processing apparatus;

FIG. 2 is a schematic diagram illustrating a structural example of a processing unit;

FIG. 3 is a schematic diagram illustrating a structural example of a nozzle of a processing fluid supply part according to a first embodiment;

FIG. 4 illustrates temperatures of processing liquids (that is, a first liquid and a second liquid) measured at multiple points of a common flow path in Measurement Example 1-3 in which measurements are performed by changing temperatures of the first liquid and the second liquid;

FIG. 5 illustrates temperatures of processing liquids (that is, a first liquid and a second liquid) measured at multiple points of a common flow path in Measurement Examples 4-6 in which measurements are performed by changing inflow rates of the first liquid and the second liquid flowing to the common flow path;

FIG. 6 is a schematic diagram illustrating a structural example of a processing fluid supply part according to a second embodiment; and

FIG. 7 is a schematic diagram for describing a structural example of a temperature adjustment nozzle according to a third embodiment.

### DETAILED DESCRIPTION OF THE EMBODIMENTS

Embodiments will now be described with reference to the accompanying drawings, wherein like reference numerals designate corresponding or identical elements throughout the various drawings.

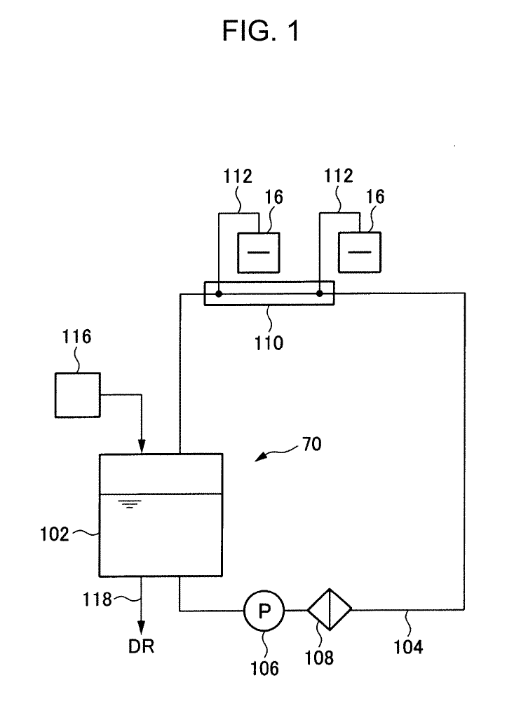

As illustrated in FIG. 1, a liquid processing apparatus includes multiple processing units (liquid processing units) 16 that each perform liquid processing with respect to a substrate, and a processing fluid supply source 70 that supplies a processing liquid to the processing units 16.

The processing liquid supply device 70 has a tank 102 that stores a processing liquid, and a circulation line 104 that extends out from the tank 102 and extends back to the tank 102. The circulation line 104 is provided with a pump 106. The pump 106 forms a circulating flow that leaves the tank 102 and passes through the circulation line 104 to return to the tank 102. On a downstream side of the pump 106, the circulation line 104 is provided with a filter 108 for removing contaminants such as particles contained in the processing liquid. When necessary, the circulation line 104 may be further provided with auxiliary equipment (for example, a heater).

One or multiple branch lines 112 are connected to a connection region 110 set in the circulation line 104. The branch lines 112 respectively supply the processing liquid flowing in the circulation line 104 to corresponding processing units 16. When necessary, each of the branch lines 112 can be provided with a flow rate adjustment mechanism (such as a flow rate control valve), a filter and the like.

The liquid processing apparatus has a tank liquid replenishing part 116 for replenishing the processing liquid or a processing liquid component to the tank 102. The tank 102 is provided with a drain part 118 for discarding the processing liquid in the tank 102.

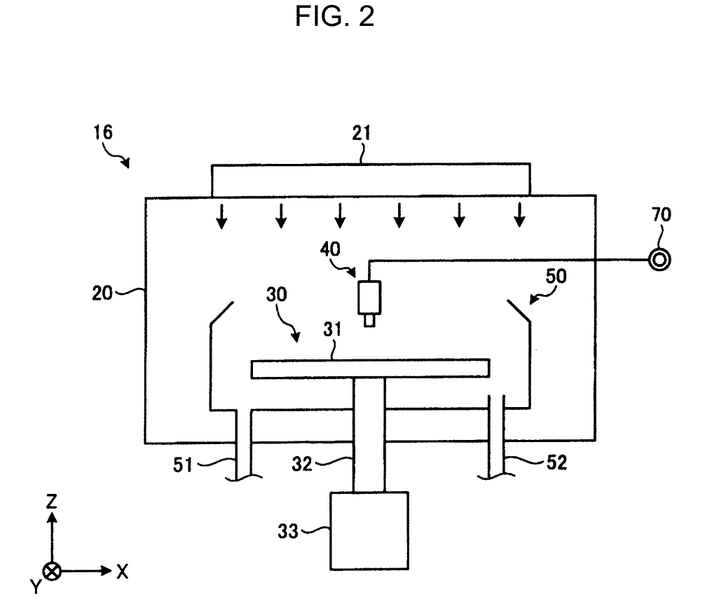

As illustrated in FIG. 2, the processing unit 16 includes a chamber 20, a substrate holding mechanism 30, a processing fluid supply part 40, and a collection cup 50.

The chamber 20 accommodates the substrate holding mechanism 30, the processing fluid supply part 40 and the collection cup 50. An FFU (Fan Filter Unit) 21 is provided in a ceiling part of the chamber 20. The FFU 21 forms a down flow in the chamber 20.

The substrate holding mechanism 30 includes a holding part 31, a support part 32, and a drive part 33. The holding part 31 horizontally holds a wafer (W). The support part 32 is a member extending in a vertical direction. A base end of the support part 32 is rotatably supported by the drive part 33. A front end part of the support part 32 horizontally supports the holding part 31. The drive part 33 causes the support part 32 to rotate about a vertical axis. Such a substrate holding mechanism 30 rotates the holding part 31 supported by the support part 32 by rotating the support part 32 using the drive part 33, and thereby, rotates the wafer (W) held by the holding part 31.

The processing fluid supply part 40 supplies a processing fluid to the wafer (W). The processing fluid supply part 40 is connected to the processing fluid supply source 70.

The collection cup 50 is positioned so as to surround the holding part 31 and collects a processing liquid scattering from the wafer (W) by the rotation of the holding part 31. At a bottom part of the collection cup 50, a drain port 51 is formed, and the processing liquid collected by the collection cup 50 is discharged from the drain port 51 to outside of the processing unit 16. Further, at the bottom part of the collection cup 50, an exhaust port 52 is formed that discharges a gas supplied from the FFU 21 to the outside of the processing unit 16.

### First Embodiment

Next, a structural example of a nozzle of the processing fluid supply part 40 is described.

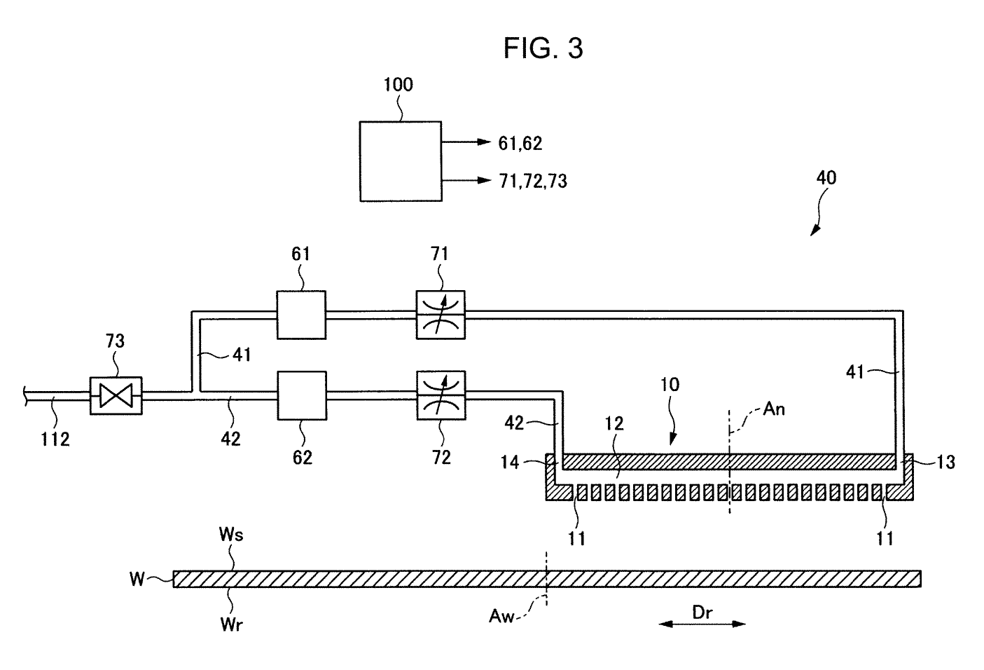

FIG. 3 is a schematic diagram illustrating a structural example of a nozzle 10 of a processing fluid supply part 40 according to a first embodiment. In FIG. 3, to facilitate understanding, elements that form the processing fluid supply part 40 and elements that are associated with the processing fluid supply part 40 are schematically illustrated, and, in particular, cross-sectional states of the nozzle 10 and the wafer (W) are illustrated.

The nozzle 10 of the present embodiment is an etching nozzle for applying an etching liquid (processing liquid) to the rotating wafer (W), and has multiple discharge ports 11, a common flow path 12, a first inflow part 13, and a second inflow part 14.

The multiple discharge ports 11 are connected to the common flow path 12 and are positioned in a direction from one end side toward the other end side of the common flow path 12 (in a radial direction (Dr) in the present embodiment), and are positioned to face a surface (Ws) of the wafer (W) held by the holding part 31 (see FIG. 2) of the substrate holding mechanism 30. The multiple discharge ports 11 illustrated in FIG. 3 are respectively positioned at mutually different positions with respect to the radial direction (Dr) of the wafer (W), and are positioned at equal intervals in a row along the radial direction (Dr) of the wafer. The positioning of the multiple discharge ports 11 is not limited to the mode illustrated in FIG. 3. For example, it is also possible that two or more discharge ports 11 are respectively positioned at mutually different positions with respect to a direction perpendicular to the radial direction (Dr) (that is, a direction perpendicular to a paper surface of FIG. 3).

The common flow path 12 extends in the radial direction (Dr) from a center portion toward a peripheral edge portion of the wafer (W) and is communicatively connected to the discharge ports 11. The common flow path 12 has a uniform diameter at least above the discharge ports 11. The entire common flow path 12 illustrated in FIG. 3 has a uniform diameter. By making the diameter of the common flow path 12 uniform, inflow rates of processing liquids (that is, a first liquid and a second liquid to be described later) flowing to the common flow path 12 can be easily controlled. A size of the diameter of the common flow path 12 is not particularly limited, but is preferably a size suitable for smoothly conveying a processing liquid from the common flow path 12 to the discharge ports 11 while preventing convection of the processing liquid in the common flow path 12. Therefore, a preferred range of the size of the diameter of the common flow path 12 can vary depending on properties of a liquid flowing to the common flow path 12 or diameters of the discharge ports or the like, but can be set to, for example, 10 mm or less, and can be preferably set to 5 mm or less in some cases.

The first inflow part 13 is communicatively connected to one end side (right side in FIG. 3) of the common flow path 12, and a first supply path 41 is connected. The second inflow part 14 is communicatively connected to the other end side (left side in FIG. 3) of the common flow path 12, and a second supply path 42 that supplies the second liquid is connected. Therefore, the first supply path 41 is connected via the first inflow part 13 to a periphery side of the wafer (W), which is the one end side of the common flow path 12, and supplies the first liquid to the one end side of the common flow path 12. The second supply path 42 is connected via the second inflow part 14 to a center side of the wafer (W), which is the other end side of the common flow path 12, and supplies the second liquid that is different from the first liquid at least in one of temperature and concentration (in the present embodiment, the second liquid that is different from the first liquid in temperature) to the other end side of the common flow path 12.

The first supply path 41 and the second supply path 42 are mutually communicatively connected via the common flow path 12, and are respectively connected to portions of the common flow path 12 that are respectively formed on radial direction (Dr) outer sides of a portion of the common flow path 12 above the discharge ports 11. The first inflow part 13 and the second inflow part 14 illustrated in FIG. 3 are respectively communicatively connected to two end portions of the common flow path 12, and the first liquid from the first supply path 41 and the second liquid from the second supply path 42 are respectively supplied to the two end portions of the common flow path 12. By respectively supplying the first liquid and the second liquid to the two end portions of the common flow path 12, the first liquid and the second liquid can be respectively smoothly flowed from the first inflow part 13 and the second inflow part 14 toward the discharge ports 11, and convection of the liquid in the common flow path 12 can be prevented. Further, the first inflow part 13 and the second inflow part 14 are respectively provided at positions that are line symmetrical when an axis (An) passing through a center of a portion of the common flow path 12 above the discharge ports 11 is taken as an axis of symmetry. The first supply path 41 and the second supply path 42 are respectively connected to the common flow path 12 at line-symmetric positions. As a result, the first liquid and the second liquid can be supplied at symmetrical positions to the common flow path 12, and supply control of the first liquid and the second liquid in the common flow path 12 can be facilitated.

The first supply path 41 and the second supply path 42 of the present embodiment are branched off and extend from one branch line 112. That is, the processing liquid from the tank 102 (see FIG. 1) is supplied to the first supply path 41 and the second supply path 42 via the common branch line 112. Therefore, the first liquid passing through the first supply path 41 and the second liquid passing through the second supply path 42 are processing liquids that have the same composition as each other, and are etching liquids for etching the wafer (W) in the present embodiment.

In the first supply path 41, a first temperature adjustment part 61 positioned on an upstream side and a first flow rate adjustment part 71 positioned on a downstream side are provided. Further, in the second supply path 42, a second temperature adjustment part 62 positioned on an upstream side and a second flow rate adjustment part 72 positioned on a downstream side are provided.

The first temperature adjustment part 61 adjusts a temperature of the first liquid flowing through the first supply path 41, and the second temperature adjustment part 62 adjusts a temperature of the second liquid flowing through the second supply path 42. Therefore, the first temperature adjustment part 61 and the second temperature adjustment part 62 function as a temperature adjustment part that adjusts a relative temperature difference between the temperature of the first liquid supplied from the first supply path 41 to the common flow path 12 and the temperature of the second liquid supplied from the second supply path 42 to the common flow path 12.

Specific devices that form the first temperature adjustment part 61 and the second temperature adjustment part 62 are not particularly limited. Any heating device capable of heating a liquid, any cooling device capable of cooling a liquid, or a device combining such a heating device and such a cooling device, can be used as the first temperature adjustment part 61 and the second temperature adjustment part 62. As a heating device, for example, an in-line heater can be suitably used. Further, as a cooling device, for example, a cooling unit that reduces a temperature of a liquid, or a media mixing unit that reduces a temperature of a liquid by adding a cooling medium such as pure water (DIW) to the liquid, can be suitably used. Further, a heat dissipation structure such as a heat dissipation channel in which heat of a liquid flowing therein is dissipated can also be used as a cooling device.

As will be described later, in the present embodiment, the first liquid having a relatively high temperature is supplied to an outer peripheral side of the wafer (W), and the second liquid having a relatively low temperature is supplied to a central portion of the wafer (W). Therefore, as an example, the first temperature adjustment part 61 preferably includes a heating device for heating the first liquid in the first supply path 41, and the second temperature adjustment part 62 preferably includes a cooling device for cooling the second liquid in the second supply path 42. However, specific structures of the first temperature adjustment part 61 and the second temperature adjustment part 62 are determined according to the temperature of the processing liquid supplied from the branch line 112 to the first supply path 41 and the second supply path 42, the temperature of the first liquid supplied from the first supply path 41 to the common flow path 12, and the temperature of the second liquid supplied from the second supply path 42 to the common flow path 12.

For example, when the temperature of the processing liquid (that is, the first liquid and the second liquid) supplied from the branch line 112 to the first supply path 41 and the second supply path 42 is higher than the temperatures of the first liquid and the second liquid supplied to the common flow path 12, both the first temperature adjustment part 61 and the second temperature adjustment part 62 may be for lied using cooling devices. Further, when the temperature of the processing liquid supplied from the branch line 112 to the first supply path 41 and the second supply path 42 is lower than the temperatures of the first liquid and the second liquid supplied to the common flow path 12, both the first temperature adjustment part 61 and the second temperature adjustment part 62 may be formed using heating devices. Further, when the temperature of the processing liquid supplied from the branch line 112 to the first supply path 41 and the second supply path 42 is the same as or close to the temperature of one of the first liquid and the second liquid supplied to the common flow path 12, it is also possible that only one of the first temperature adjustment part 61 and the second temperature adjustment part 62 is provided and the other is not provided.

The first flow rate adjustment part 71 adjusts a flow rate of the first liquid flowing through the first supply path 41, and the second flow rate adjustment part 72 adjusts a flow rate of the second liquid flowing through the second supply path 42. Therefore, the first flow rate adjustment part 71 and the second flow rate adjustment part 72 function as a flow rate adjustment part that adjusts a relative flow rate difference between the flow rate of the first liquid supplied from the first supply path 41 to the common flow path 12 and the flow rate of the second liquid supplied from the second supply path 42 to the common flow path 12. Specific devices that form the first flow rate adjustment part 71 and the second flow rate adjustment part 672 are not particularly limited. The first flow rate adjustment part 71 and the second flow rate adjustment part 72 can each be formed using any device such as a flow rate adjustment valve capable of changing a flow rate of a liquid.

An on-off valve 73 is provided in the branch line 112. When the on-off valve 73 is opened, the processing liquid flows from the branch line 112 to the first supply path 41 and the second supply path 42. When the on-off valve 73 is closed, the branch line 112 is blocked, and the flow of the processing liquid from the branch line 112 to the first supply path 41 and the second supply path 42 is stopped. Therefore, by controlling opening and closing of the on-off valve 73, presence or absence of discharge of a processing liquid from the nozzle 10 (that is, the discharge ports 11) can be controlled. However, it is also possible that the on-off valve 73 is not provided. When the on-off valve 73 is not provided, by controlling opening and closing of the first flow rate adjustment part 71 and the second flow rate adjustment part 72, presence or absence of discharge of a processing liquid from the nozzle 10 can be controlled.

The above-described first temperature adjustment part 61, second temperature adjustment part 62, first flow rate adjustment part 71, second flow rate adjustment part 72 and on-off valve 73 are connected to a controller 100 and are controlled by the controller 100. The controller 100 may be formed by using a single device or by using a combination of multiple devices. Therefore, it is also possible to separately provide a controller that controls one or more devices among the first temperature adjustment part 61, the second temperature adjustment part 62, the first flow rate adjustment part 71, the second flow rate adjustment part 72 and the on-off valve 73 and a controller that controls the other devices.

In the processing fluid supply part 40 and the nozzle 10 having the above-described structures, the one end side of the common flow path 12, to which the first supply path 41 is connected, is formed on a radial direction (Dr) outer side of the wafer (W); and the other end side of the common flow path 12, to which the second supply path 42 is connected, is formed on a radial direction (Dr) inner side of the wafer (W). The first liquid supplied from the first supply path 41 to the common flow path 12 is higher in temperature than the second liquid supplied from the second supply path 42 to the common flow path 12. Therefore, the first liquid that is higher in temperature than the second liquid is supplied to the radial direction (Dr) outer side of the surface (Ws) of the wafer (W). As a result, an etching rate on the radial direction (Dr) outer side of the wafer (W) can be prevented from becoming excessively small.

For example, when it is desired to perform uniform etching over the entire wafer (W), the temperature difference between the first liquid supplied from the first supply path 41 to the first inflow part 13 and the second liquid supplied from the second supply path 42 to the first inflow part 13 is adjusted by the first temperature adjustment part 61 and the second temperature adjustment part 62 such that the processing liquids (that is, the first liquid and the second liquid) discharged from the discharge ports 11 do not become excessively different in temperature at different radial direction positions on the surface (Ws) of the wafer (W) (preferably, the temperature is substantially the same regardless of the radial direction positions). As a result, the etching rate on the entire surface (Ws) of the wafer (W) can be formed uniform, and uniform etching over the entire wafer (W) can be realized.

When it is desired to allow etching to proceed more on a radial direction (Dr) outer side of the wafer (W) than on a radial direction (Dr) inner side of the wafer (W), the temperature difference between the first liquid supplied from the first supply path 41 and the second liquid supplied from the second supply path 42 is adjusted by the first temperature adjustment part 61 and the second temperature adjustment part 62 such that the temperature of the processing liquids (that is, the first liquid and the second liquid) discharged from the discharge ports 11 is relatively high on a radial direction (Dr) outer side and is relatively low on a radial direction (Dr) inner side on the surface (Ws) of the wafer (W). As a result, an etching rate on a radial direction (Dr) outer side of the wafer (W) can be larger than an etching rate on a radial direction (Dr) inner side of the wafer (W), and etching on a radial direction (Dr) outer side of the wafer (W) can proceed more than etching on a radial direction (Dr) inner side of the wafer (W).

In the common flow path 12, the first liquid from the first supply path 41 and the second liquid from the second supply path 42 substantially do not mix with each other. That is, the first liquid flowing from the first supply path 41 to the common flow path 12 via the first inflow part 13 is discharged from multiple discharge ports 11 positioned on the one end side (the right side in FIG. 3). On the other hand, the second liquid flowing from the second supply path 42 to the common flow path 12 via the second inflow part 14 is discharged from multiple discharge ports 11 positioned on the other end side (the left side in FIG. 3). A boundary between the first liquid and the second liquid in the common flow path 12, that is, a boundary between the discharge ports 11 discharging the first liquid and the discharge ports 11 discharging the second liquid is determined according the flow rate of the first liquid flowing from the first supply path 41 to the common flow path 12 and the flow rate of the second liquid flowing from the second supply path 42 to the common flow path 12.

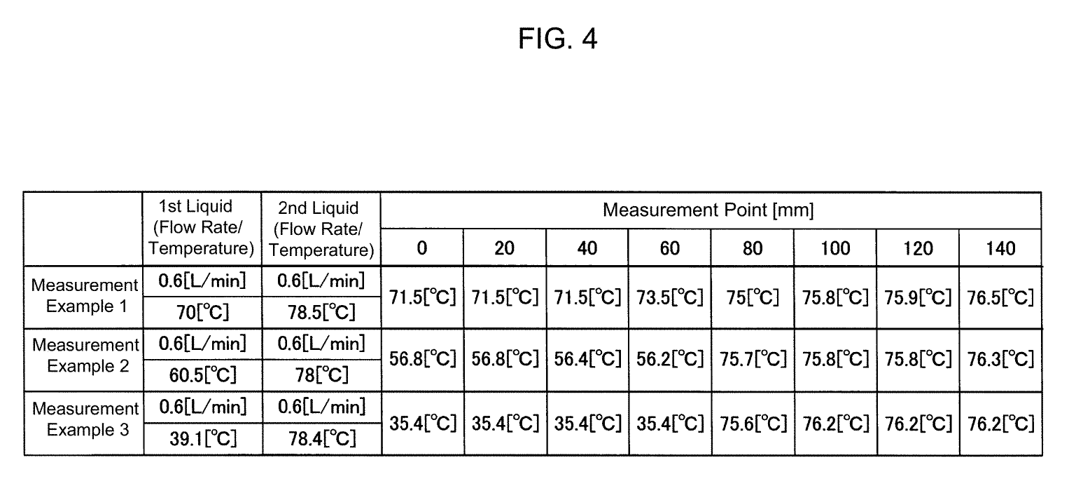

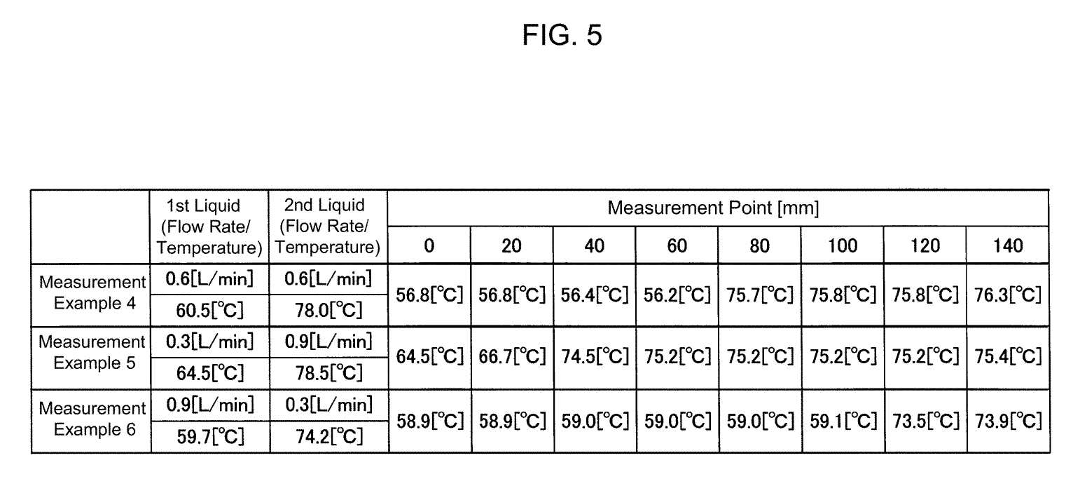

FIG. 4 illustrates temperatures of the processing liquids (that is, the first liquid and the second liquid) measured at multiple points of the common flow path 12 in Measurement Example 1-3 in which measurements are performed by changing the temperatures of the first liquid and the second liquid. FIG. 5 illustrates temperatures of the processing liquids (that is, the first liquid and the second liquid) measured at multiple points of the common flow path 12 in Measurement Example 4-6 in which measurements are performed by changing the inflow rates of the first liquid and the second liquid flowing to the common flow path 12.

The “measurement points” illustrated in FIGS. 4 and 5 each indicate a distance from the other end (the left side end in FIG. 3) of the common flow path 12 in the radial direction (Dr). The measurements of Measurement Example 1-6 are performed using a nozzle 10 in which the common flow path 12 has a size of 140 mm in the radial direction (Dr). Therefore, in FIGS. 4 and 5, the measurement point of “0” mm represents a point at which the second liquid flows from the second supply path 42 to the common flow path 12; and the measurement point of “140 mm” represents a point at which the first liquid flows from the first supply path 41 to the common flow path 12.

The “first liquid (flow rate/temperature)” illustrated in FIGS. 4 and 5 represents the flow rate of the first liquid from the first flow rate adjustment part 71 illustrated in FIG. 3, and the temperature of the first liquid immediately after flowing out from the first temperature adjustment part 61. For example, in Measurement Example 1, the first liquid flows out from the first flow rate adjustment part 71 at a flow rate of 0.6 L/min (liter/minute), and the temperature of the first liquid immediately after flowing out from the first temperature adjustment part 61 is 70° C. Further, the “second liquid (flow rate/temperature)” illustrated in FIGS. 4 and 5 represents the flow rate of the second liquid from the second flow rate adjustment part 72 illustrated in FIG. 3, and the temperature of the second liquid immediately after flowing out from the second temperature adjustment part 62.

In Measurement Example 1-3 illustrated in FIG. 4, the flow rate of the first liquid and the flow rate of the second liquid are the same (that is, 0.6 L/min), and the temperature variation of the processing liquid is relatively intense between the measurement point of 60 mm and the measurement point of 80 mm. Therefore, in Measurement Example 1-3, it is clear that a middle point (that is, a point of 70 mm) between the measurement point of 60 mm and the measurement point of 80 mm is the boundary between the first liquid from the first supply path 41 and the second liquid from the second supply path 42.

In Measurement Example 4-6 illustrated in FIG. 5, the flow rate of the first liquid and the flow rate of the second liquid are varied. That is, in Measurement Example 4, the flow rate of the first liquid and the flow rate of the second liquid are set to be the same (that is, 0.6 L/min); in Measurement Example 5, the flow rate of the first liquid is set to be smaller than the flow rate of the second liquid; and in Measurement Example 6, the flow rate of the first liquid is set to be larger than the flow rate of the second liquid. From the temperature variations of the processing liquids at the measurement points illustrated in FIG. 5, in Measurement Example 4, a middle point (that is, a point of 70 mm) between the measurement point of 60 mm and the measurement point of 80 mm is estimated to be the boundary between the first liquid and the second liquid; in Measurement Example 5, the boundary between the first liquid and the second liquid is estimated to be between the measurement point of 20 mm and the measurement point of 40 mm; and, in Measurement Example 6, the boundary between the first liquid and the second liquid is estimated to be between the measurement point of 100 mm and the measurement point of 120 mm.

As is clear from the results of Measurement Example 1-6 illustrated in FIGS. 4 and 5, proportions occupied by the first liquid and the second liquid in the common flow path 12 basically are not influenced by the temperatures of the liquids, but are solely determined based on the inflow rates of the liquids flowing to the common flow path 12. That is, among the first liquid and the second liquid, a liquid flowing to the common flow path 12 at a larger inflow rate is discharged from discharge ports 11 in a wider range. Therefore, for example, when it is desired to widen an influence range of the first liquid on the wafer (W), it is sufficient to increase the first liquid flowing from the first supply path 41 to the common flow path 12; and, when it is desired to narrow the influence range of the first liquid on the wafer (W), it is sufficient to reduce the first liquid flowing from the first supply path 41 to the common flow path 12.

Therefore, when the liquid processing apparatus and the nozzle 10 of the present embodiment are used, by simply varying a flow rate balance between the first liquid and the second liquid flowing to the common flow path 12, an etching profile of the surface (Ws) of the wafer (W) can be varied. In this way, by only the nozzle 10 provided on the surface (Ws) side of the wafer (W), it is possible to increase in-plane uniformity of the etching of the wafer (W) or to allow etching of an outer peripheral portion of the wafer (W) to proceed more than a center portion of the wafer (W).

According to the liquid processing apparatus and the nozzle 10 of the present embodiment, by adjusting the temperatures and the flow rates of the first liquid and the second liquid, liquid processing according to a position such as a center position or a peripheral position of the wafer (W) can be realized with a simple structure. In particular, in the present embodiment, by adjusting the flow rates and the temperatures of the first liquid and the second liquid supplied to the common flow path 12 of the nozzle 10, it is possible to allow an etching process of the wafer (W) to locally proceed. For example, by setting the temperature of the first liquid significantly higher than the temperature of the second liquid, it is possible to allow etching of an outer peripheral portion of the wafer (W) to locally proceed. In this way, in a liquid processing method using the above-described liquid processing apparatus, by including a process of supplying a first etching liquid from the first supply path 41 to the common flow path 12 and supplying a second etching liquid (having a temperature lower than that of the first etching liquid) from the second supply path 42 to the common flow path 12, liquid processing according to a position such as a center position or a peripheral position of the wafer (W) can be realized with a simple structure.

In the above description, an example is illustrated in which the first supply path 41 and the second supply path 42 are connected to the common tank 102 via the common branch line 112. However, it is also possible that the first supply path 41 and the second supply path 42 are respectively connected to separate tanks via separate branch lines. In this case, processing liquids (that is, the first liquid and the second liquid) for which temperature adjustment has been performed in advance may be stored in separate tanks. In such a case, the first temperature adjustment part 61 and the second temperature adjustment part 62 may be omitted.

### Second Embodiment

In the above-described first embodiment, the case where the temperatures of the first liquid and the second liquid supplied to the common flow path 12 are mutually different has been described. In a second embodiment, a case where concentrations of the first liquid and the second liquid supplied to the common flow path 12 are mutually different is described. That is, in the present embodiment, a concentration of a component contributing to the etching of the wafer (W) (hereinafter also simply referred to as an “etching component”) is higher in the first liquid than in the second liquid.

Such first liquid and second liquid can be realized by various kinds of liquids. The first liquid and the second liquid in the present embodiment have the same component. However, the present invention is not limited to this. For example, it is also possible that the first liquid and the second liquid are formed by different kinds of liquids having mutually different compositions. In this case, it is sufficient that, among the first liquid and the second liquid, at least the first liquid is an etching liquid. Further, the first liquid and the second liquid contain the same solute that contributes to etching. However, it is also possible that a concentration of the solute is higher in the first liquid than in the second liquid.

The first supply path 41 and the second supply path 42 of the present embodiment may be connected to the common tank 102 via the common branch line 112 similar to the first embodiment illustrated in FIG. 3, or may be respectively connected separate tanks via separate branch lines.

In the present embodiment, when the first supply path 41 and the second supply path 42 are connected to the common tank 102 via the common branch line 112, a concentration adjustment part that varies a concentration of an etching component is provided in at least one of the first supply path 41 and the second supply path 42.

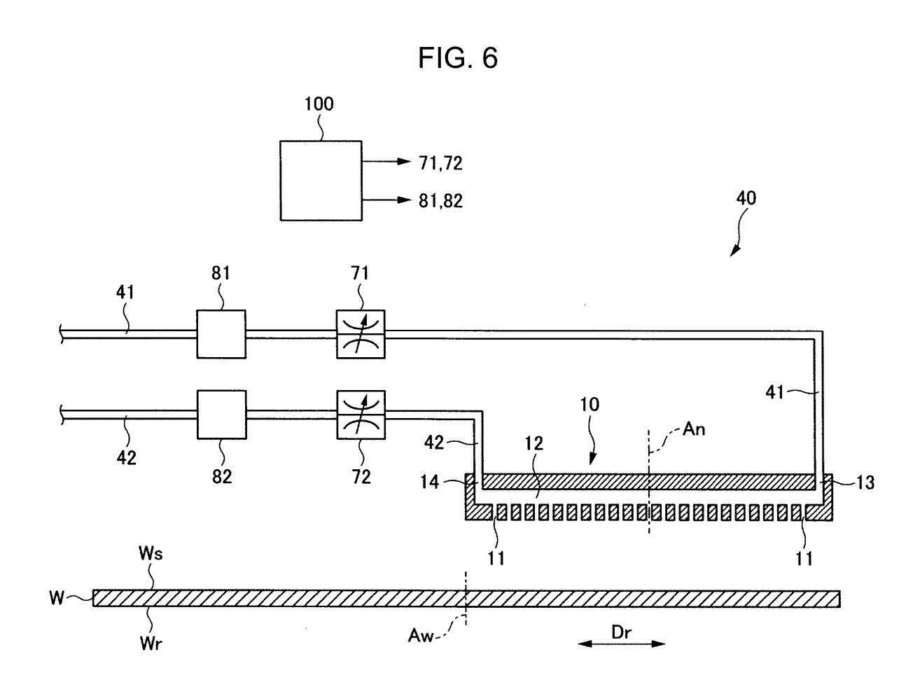

FIG. 6 is a schematic diagram illustrating a structural example of a processing fluid supply part 40 according to the second embodiment. In FIG. 6, an element that is the same as or similar to an element illustrated in FIG. 3 is indicated using the same reference numeral, and detailed description about the element is omitted. In the example illustrated in FIG. 6, instead of the above-described first temperature adjustment part 61 and second temperature adjustment part 62, a first concentration adjustment part 81 and a second concentration adjustment part 82 are respectively provided in the first supply path 41 and the second supply path 42. That is, the first concentration adjustment part 81 can vary a concentration of an etching component contained in the first liquid flowing through the first supply path 41, and the second concentration adjustment part 82 can vary a concentration of an etching component contained in the second liquid flowing through the second supply path 42.

The first concentration adjustment part 81 and the second concentration adjustment part 82 can each be formed using any device. For example, the first concentration adjustment part 81 and the second concentration adjustment part 82 can each be formed using a device that reduces the concentration of the etching component by adding a solvent such as pure water (DIW) to the first liquid and/or the second liquid, a device that adds an etching component to the first liquid and/or the second liquid, or a device that removes a part of a solvent from the first liquid and/or the second liquid.

Also in the present embodiment, the one end side of the common flow path 12, to which the first supply path 41 is connected, is positioned on a radial direction (Dr) outer side of the wafer (W); and the other end side of the common flow path 12, to which the second supply path 42 is connected, is positioned on a radial direction (Dr) inner side of the wafer (W). Therefore, from a point of view of suppressing reduction in an etching rate on an outer side of the wafer (W), it is preferable to make the concentration of the etching component of the first liquid higher than the concentration of the etching component of the second liquid.

In the present embodiment, when the first supply path 41 and the second supply path 42 are respectively connected to separate tanks via separate branch lines (not shown in the drawings), it is possible that the above-described first concentration adjustment part 81 and second concentration adjustment part 82 are not provided. That is, by respectively storing in the tanks the processing liquids (that is, the first liquid and the second liquid) for each of which concentration adjustment for the etching component has been performed in advance, the above-described first concentration adjustment part 81 and second concentration adjustment part 82 are not required.

In the above-described example (see FIG. 6), the first temperature adjustment part 61 and the second temperature adjustment part 62 are not provided. However, it is also possible that, in the case where the first supply path 41 and the second supply path 42 are connected to the common tank 102 via the common branch line 112, or in the case where the first supply path 41 and the second supply path 42 are respectively connected to separate tanks via separate branch lines, the first temperature adjustment part 61 and the second temperature adjustment part 62 are respectively provided in the first supply path 41 and the second supply path 42. In this case, by adjusting the concentrations of the etching components and the temperatures of the first liquid and the second liquid, the etching rate of the wafer (W) can be flexibly adjusted.

According to the processing unit 16 and the nozzle 10 of the present embodiment, by adjusting the concentrations of the etching components and the flow rates of the first liquid and the second liquid, liquid processing according to a position such as a center position or a peripheral position of the wafer (W) can be realized with a simple structure. In this way, in a liquid processing method using the above-described liquid processing apparatus, by including a process of supplying a first etching liquid from the first supply path 41 to the common flow path 12 and supplying a second etching liquid (having a concentration lower than that of the first etching liquid) from the second supply path 42 to the common flow path 12, liquid processing according to a position such as a center position or a peripheral position of the wafer (W) can be realized with a simple structure.

### Third Embodiment

In the above-described first embodiment and second embodiment, the cases where the first liquid and the second liquid are etching liquids are described. However, it is also possible that the first liquid and the second liquid are each a liquid having a function other than etching. In the present embodiment, a case where the first liquid and second liquid are temperature adjustment liquids for adjusting a temperature of the wafer (W) is described.

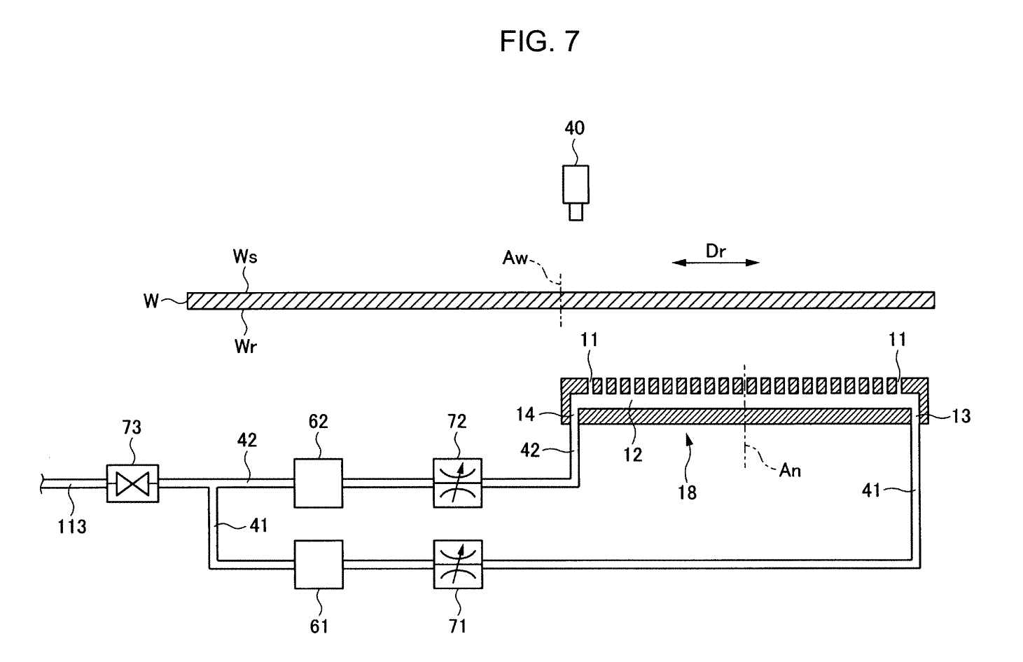

FIG. 7 is a schematic diagram for describing a structural example of a temperature adjustment nozzle 18 according to a third embodiment. In FIG. 7, an element that is the same as or similar to an element of the etching nozzle 10 illustrated in FIG. 3 is indicated using the same reference numeral, and detailed description about the element is omitted.

Similar to the etching nozzle 10 illustrated in FIG. 3, the temperature adjustment nozzle 18 illustrated in FIG. 7 has multiple discharge ports 11 that are positioned in a direction from one end side toward the other end side of a common flow path 12, the common flow path 12 that is communicatively connected to the discharge ports 11, and a first inflow part 13 and a second inflow part 14 that are respectively communicatively connected to the one end side and the other end side of the common flow path 12. A first supply path 41 supplying a first liquid is connected to the first inflow part 13, and a second supply path 42 supplying a second liquid is connected to the second inflow part 14.

The first liquid and the second liquid that are supplied to the common flow path 12 of the temperature adjustment nozzle 18 are temperature adjustment liquids having mutually different temperatures. The temperature adjustment liquids are applied to a back surface (Wr) of a rotating wafer (W). That is, a temperature adjustment liquid such as pure water (DIW) is stored in a tank (not illustrated in FIG. 7) to which the first supply path 41 and the second supply path 42 are communicatively connected via a branch line 113, and the temperature adjustment liquid is supplied from the tank to the first supply path 41 and the second supply path 42 via the branch line 113. The temperature adjustment liquid (that is, the first liquid) flowing to the first supply path 41 and the temperature adjustment liquid (that is, the second liquid) flowing to the second supply path 42 are respectively subjected to temperature adjustment by the first temperature adjustment part 61 and the second temperature adjustment part 62, and are sent toward the common flow path 12 of the temperature adjustment nozzle 18.

The discharge ports 11 of the temperature adjustment nozzle 18 are positioned so as to face the back surface (Wr) of the wafer (W), and the temperature adjustment liquids (that is, the first liquid and the second liquid) discharged from the discharge ports 11 are applied to the back surface (Wr) of the wafer (W). On the other hand, a processing liquid (etching liquid) discharged from the processing fluid supply part 40 is applied to the surface (Ws) of the wafer (W).

Also in the present embodiment, the one end side of the common flow path 12, to which the first supply path 41 is connected, is positioned on a radial direction (Dr) outer side of the wafer (W); and the other end side of the common flow path 12, to which the second supply path 42 is connected, is positioned on a radial direction (Dr) inner side of the wafer (W). From a point of view of suppressing reduction in an etching rate on an outer peripheral portion of the wafer (W), it is preferable to make the temperature of the first liquid higher than the temperature of the second liquid. That is, an etching liquid supplied to near the center of the surface (Ws) of the wafer (W) decreases in temperature when the etching liquid reaches the outer peripheral portion of the wafer (W), and the etching rate tends to decrease due to the temperature decrease. By using the temperature adjustment nozzle 18 of the present embodiment to worm the outer peripheral portion of the wafer (W) from the back surface (Wr) side with the temperature adjustment liquids, the temperature decrease of the etching liquid in the outer peripheral portion can be prevented, and the decrease in the etching rate in the outer peripheral portion of the wafer (W) can be suppressed.

According to the temperature adjustment nozzle 18 of the present embodiment, by adjusting the temperatures and the flow rates of the first liquid and the second liquid, an etching process according to a position such as a center position or a peripheral position of the wafer (W) can be realized with a simple structure. In this way, in a liquid processing method using the above-described liquid processing apparatus, by including a process of supplying a first temperature adjustment liquid from the first supply path 41 to the common flow path 12 and supplying a second temperature adjustment liquid (having a temperature lower than that of the first temperature adjustment liquid) from the second supply path 42 to the common flow path 12, liquid processing according to a position such as a center position or a peripheral position of the wafer (W) can be realized with a simple structure.

Further improvements have been demanded in the above-described conventional technology in terms of enhancing in-plane uniformity of substrate processing. For example, in the above-described conventional technology, since an etching liquid supplied to a center portion of a substrate decreases in temperature when the etching liquid reaches an outer peripheral portion of the substrate, an etching rate at the outer peripheral portion of the substrate is smaller than an etching rate at the center portion of the substrate.

The liquid processing apparatus and the liquid processing method according to embodiments of the present invention allow liquid processing according to a position such as a center position or a peripheral position of a substrate to be realized with a simple structure.

One aspect of the present invention relates to a liquid processing apparatus that includes: a holding mechanism that holds a substrate; a rotation mechanism that rotates the substrate held by the holding mechanism; a nozzle that is positioned to face a surface of the substrate; and a first supply path and a second supply path that are connected to the nozzle. The nozzle has a common flow path that extends in a radial direction from a center portion toward a peripheral portion of substrate; and multiple discharge ports that are connected to the common flow path and are positioned in the radial direction. The first supply path is connected to the common flow path on a periphery side of the substrate and supplies a first liquid to the common flow path. The second supply path is connected to the common flow path on a center side of the substrate and supplies a second liquid to the common flow path, the second liquid being different from the first liquid at least in one of temperature and concentration. The first supply path and the second supply path are communicatively connected to each other via the common flow path.

Another aspect of the present invention relates to a liquid processing method using a liquid processing apparatus. The liquid processing apparatus includes: a holding mechanism that holds a substrate; a rotation mechanism that rotates the substrate held by the holding mechanism; a nozzle that is positioned to face a surface of the substrate; and a first supply path and a second supply path that are connected to the nozzle. The nozzle has a common flow path that extends in a radial direction from a center portion toward a peripheral portion of substrate; and multiple discharge ports that are connected to the common flow path and are positioned in the radial direction. The first supply path is connected to the common flow path on a periphery side of the substrate. The second supply path is connected to the common flow path on a center side of the substrate. The first supply path and the second supply path are communicatively connected to each other via the common flow path. The liquid processing method includes a process of supplying a first etching liquid from the first supply path to the common flow path and supplying a second etching liquid from the second supply path to the common flow path, the second etching liquid having a temperature lower than that of the first etching liquid.

Another aspect of the present invention relates to a liquid processing method using a liquid processing apparatus. The liquid processing apparatus includes: a holding mechanism that holds a substrate; a rotation mechanism that rotates the substrate held by the holding mechanism; a nozzle that is positioned to face a surface of the substrate; and a first supply path and a second supply path that are connected to the nozzle. The nozzle has a common flow path that extends in a radial direction from a center portion toward a peripheral portion of substrate; and multiple discharge ports that are connected to the common flow path and are positioned in the radial direction. The first supply path is connected to the common flow path on a periphery side of the substrate. The second supply path is connected to the common flow path on a center side of the substrate. The first supply path and the second supply path are communicatively connected to each other via the common flow path. The liquid processing method includes a process of supplying a first etching liquid from the first supply path to the common flow path and supplying a second etching liquid from the second supply path to the common flow path, the second etching liquid having a concentration lower than that of the first etching liquid.

Another aspect of the present invention relates to a liquid processing method using a liquid processing apparatus. The liquid processing apparatus includes: a holding mechanism that holds a substrate; a rotation mechanism that rotates the substrate held by the holding mechanism; a nozzle that is positioned to face a surface of the substrate; and a first supply path and a second supply path that are connected to the nozzle. The nozzle has a common flow path that extends in a radial direction from a center portion toward a peripheral portion of substrate; and multiple discharge ports that are connected to the common flow path and are positioned in the radial direction. The first supply path is connected to the common flow path on a periphery side of the substrate. The second supply path is connected to the common flow path on a center side of the substrate. The first supply path and the second supply path are communicatively connected to each other via the common flow path. The liquid processing method includes a process of supplying a first temperature adjustment liquid from the first supply path to the common flow path and supplying a second temperature adjustment liquid from the second supply path to the common flow path, the second temperature adjustment liquid having a temperature lower than that of the first temperature adjustment liquid.

According to embodiments of the present invention, liquid processing according to a position such as a center position or a peripheral position of a substrate can be realized with a simple structure.

Obviously, numerous modifications and variations of the present invention are possible in light of the above teachings. It is therefore to be understood that within the scope of the appended claims, the invention may be practiced otherwise than as specifically described herein.

1. A liquid processing apparatus, comprising:
a holding device configured to hold a substrate;
a rotation device configured to rotate the substrate held by the holding device; and
a processing fluid supply device comprising a nozzle positioned to face a surface of the substrate, a first supply path connected to the nozzle, and a second supply path connected to the nozzle such that the processing fluid supply device is configured to supply a processing liquid to the substrate,
wherein the nozzle of the processing fluid supply device has a common flow path extending in a radial direction from a center portion toward a peripheral portion of the substrate, and a plurality of discharge ports connected to the common flow path and positioned in the radial direction, the first supply path of the processing fluid supply device is connected to the common flow path on a periphery side of the substrate and is configured to supply a first liquid to the common flow path, the second supply path of the processing fluid supply device is connected to the common flow path on a center side of the substrate and is configured to supply a second liquid to the common flow path such that the second liquid is different from the first liquid in at least one of temperature and concentration, and the first supply path and the second supply path of the processing fluid supply device are communicatively connected to each other via the common flow path.

2. The liquid processing apparatus of claim 1, wherein the processing fluid supply device has a temperature adjustment device configured to adjust temperatures of the first and second liquids such that the temperature of the first liquid is higher than the temperature of the second liquid.

3. The liquid processing apparatus of claim 1, wherein the processing fluid supply device has a concentration adjustment device configured to adjust concentrations of solutes in the first and second liquids such that the concentration of the solute in the first liquid is higher than the concentration of the solute in the second liquid.

4. The liquid processing apparatus of claim 1, wherein the common flow path has a uniform diameter at least above the discharge ports.

5. The liquid processing apparatus of claim 1, wherein the first supply path and second supply path of the processing fluid supply device are connected to portions of the common flow path respectively such that the portions of the common flow path are positioned on outer sides of a portion of the common flow path above the discharge ports respectively.

6. The liquid processing apparatus of claim 1, wherein the first supply path and second supply path of the processing fluid supply device are connected to the common flow path at positions that are line symmetrical where an axis passing through a center of a portion of the common flow path above the discharge ports is an axis of symmetry.

7. The liquid processing apparatus of claim 1, wherein the processing fluid supply device has a flow rate adjustment device configured to adjust a flow rate difference between a flow rate of the first liquid supplied from the first supply path to the common flow path and a flow rate of the second liquid supplied from the second supply path to the common flow path.

8. The liquid processing apparatus of claim 1, wherein the processing fluid supply device has a temperature adjustment device configured to adjust a temperature difference between a temperature of the first liquid supplied from the first supply path to the common flow path and a temperature of the second liquid supplied from the second supply path to the common flow path.

9. The liquid processing apparatus of claim 2, wherein the processing fluid supply device has a concentration adjustment device configured to adjust concentrations of solutes in the first and second liquids such that the concentration of the solute in the first liquid is higher than the concentration of the solute in the second liquid.

10. The liquid processing apparatus of claim 2, wherein the common flow path has a uniform diameter at least above the discharge ports.

11. The liquid processing apparatus of claim 2, wherein the first supply path and second supply path of the processing fluid supply device are connected to portions of the common flow path respectively such that the portions of the common flow path are positioned on outer sides of a portion of the common flow path above the discharge ports respectively.

12. The liquid processing apparatus of claim 2, wherein the first supply path and second supply path of the processing fluid supply device are connected to the common flow path at positions that are line symmetrical where an axis passing through a center of a portion of the common flow path above the discharge ports is an axis of symmetry.

13. The liquid processing apparatus of claim 2, wherein the processing fluid supply device has a flow rate adjustment device configured to adjust a flow rate difference between a flow rate of the first liquid supplied from the first supply path to the common flow path and a flow rate of the second liquid supplied from the second supply path to the common flow path.

14. The liquid processing apparatus of claim 2, wherein the processing fluid supply device has a temperature adjustment device configured to adjust a temperature difference between a temperature of the first liquid supplied from the first supply path to the common flow path and a temperature of the second liquid supplied from the second supply path to the common flow path.

15. The liquid processing apparatus of claim 3, wherein the common flow path has a uniform diameter at least above the discharge ports.

16. The liquid processing apparatus of claim 3, wherein the first supply path and second supply path of the processing fluid supply device are connected to portions of the common flow path respectively such that the portions of the common flow path are positioned on outer sides of a portion of the common flow path above the discharge ports respectively.

17. A liquid processing method, comprising:
holding a substrate with a holding device configured to hold the substrate;
rotating the substrate with a rotation device configured to rotate the substrate held by the holding device; and
supplying, to the substrate, a processing liquid from a processing fluid supply device comprising a nozzle positioned to face a surface of the substrate, a first supply path connected to the nozzle, and a second supply path connected to the nozzle such that the processing fluid supply device supplies the processing liquid to the substrate,
wherein the nozzle of the processing fluid supply device has a common flow path extending in a radial direction from a center portion toward a peripheral portion of the substrate, and a plurality of discharge ports connected to the common flow path and positioned in the radial direction, the first supply path of the processing fluid supply device is connected to the common flow path on a periphery side of the substrate and configured to supply a first liquid to the common flow path, the second supply path of the processing fluid supply device is connected to the common flow path on a center side of the substrate and configured to supply a second liquid to the common flow path such that the second liquid is different from the first liquid in at least one of temperature and concentration, the first supply path and the second supply path of the processing fluid supply device are communicatively connected to each other via the common flow path, and the first liquid comprising a first etching liquid is supplied from the first supply path to the common flow path and the second liquid comprising a second etching liquid is supplied from the second supply path to the common flow path such that at least one of temperature and concentration of the second etching liquid is lower than at least one of temperature and concentration of the first etching liquid.

18. The liquid processing method of claim 17, wherein the first liquid comprising the first etching liquid is supplied from the first supply path to the common flow path, and the second liquid comprising the second etching liquid is supplied from the second supply path to the common flow path such that the temperature of the second etching liquid is lower than the temperature of the first etching liquid.

19. The liquid processing method of claim 17, wherein the first liquid comprising the first etching liquid is supplied from the first supply path to the common flow path and the second liquid comprising the second etching liquid is supplied from the second supply path to the common flow path such that the concentration of the second etching liquid is lower than the concentration of the first etching liquid.

20. A liquid processing method, comprising:
holding a substrate with a holding device configured to hold the substrate;
rotating the substrate with a rotation device configured to rotate the substrate held by the holding device; and
supplying, to the substrate, a processing liquid from a processing fluid supply device comprising a nozzle positioned to face a surface of the substrate, a first supply path connected to the nozzle, and a second supply path connected to the nozzle such that the processing fluid supply device supplies the processing liquid to the substrate,
wherein the nozzle of the processing fluid supply device has a common flow path extending in a radial direction from a center portion toward a peripheral portion of the substrate, and a plurality of discharge ports connected to the common flow path and positioned in the radial direction, the first supply path of the processing fluid supply device is connected to the common flow path on a periphery side of the substrate and configured to supply a first liquid to the common flow path, the second supply path of the processing fluid supply device is connected to the common flow path on a center side of the substrate and configured to supply a second liquid to the common flow path such that the second liquid is different from the first liquid in at least one of temperature and concentration, the first supply path and the second supply path of the processing fluid supply device are communicatively connected to each other via the common flow path, and the first liquid comprising a first temperature adjustment liquid is supplied from the first supply path to the common flow path and the second liquid comprising a second temperature adjustment liquid is supplied from the second supply path to the common flow path such that a temperature of the second temperature adjustment liquid is lower than a temperature of the first temperature adjustment liquid.
